(19) United States
(12) Patent Application Publication
(10) Pub. No.: US 2006/0091538 A1
(43) Pub. Date: May 4, 2006

(54) Low profile and tight pad-pitch land-grid-array (LGA) socket

(76) Inventor: Ashok N. Kabadi, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/982,103

(22) Filed: Nov. 4, 2004

(51) Int. Cl. H01L 21/48; H01L 29/40

(52) U.S. Cl. 257/737; 257/782; 438/118

(57) ABSTRACT

The apparatus and method described herein are for coupling an integrated circuit to a circuit board through a low profile compression socket. A plurality of compressible columns disposed in a substrate, when compressed, make electrical connection to a first set of pads on an integrated circuit and to a plurality of conductive paths disposed in an interposer, wherein the conductive paths make electrical contact with a second set of connection pads coupled to a circuit board.

### FIELD

This invention relates to the field of integrated circuits and, in particular, to coupling integrated circuits to circuit boards.

### BACKGROUND

Advances in semi-conductor processing and logic design have permitted an increase in the amount of logic that may be present on integrated circuit devices. As a result, integrated circuits have increased the number of input, output, power, and ground signals that are used to power the integrated circuits, to communicate with external devices, and to receive data/instructions. Moreover, the physical size of a typical integrated circuit package has grown to accommodate the increase in the number of pins/pads.

Often, integrated circuits are packaged individually and later coupled to a circuit board to communicate with other devices. One method of coupling an integrated circuit to a circuit board, such as a motherboard or expansion card, includes directly soldering the integrated circuit device to the circuit board. Although, this creates an adequate electrical connection between the pads of the device and the circuit board, the direct soldering of the device creates potential upgrade and swapability limitations. For example, if a microprocessor is directly soldered to a motherboard and is later found to be defective, then the microprocessor needs to be de-soldered. The de-soldering, replacement, and re-soldering process is potentially expensive and tedious.

Therefore, it is common in the industry to use compression sockets to couple an integrated circuit to a circuit board. For example, current Microprocessors, from Intel Corporation in Santa Clara, Calif., are typically, connected to a motherboard using a grid array compression socket.

FIG. 1 illustrates prior art grid array compression socket 107 used to make an electrical connection between microprocessor 105 and motherboard 135. Microprocessor 105 may be in a package, such as a flip-chip pin grid array (FCPGA) package or other package. Clamping plates on the bottom of motherboard 134 and on the top of microprocessor 105, which are not illustrated in FIG. 1, typically exert a compression force to compress socket 107. Compressible clips 120 molded in plastic substrate 115, when compressed, make electrical connection between connection pad 110 and connection pad 130. However, compressible clips 120, when transmitting high frequency signals, may have high inductance and capacitance characteristics that adversely affect the signal integrity of the high frequency signals.

Another style of compression socket developed by Tyco Electronics Corp., metallized-particle-interconnect (MPI) socket, is designed to have good high frequency inductance and capacitance characteristics by utilizing a polymer based compressible column with silver particles. A typical compressed height of an MPI column is 0.036 inches. However, on current integrated circuits active and passive devices, such as capacitors coupled to the microprocessor, require more space between the integrated circuit and the circuit board than 0.036 inches.

### BRIEF DESCRIPTION OF THE DRAWINGS

The present invention is illustrated by way of example and not intended to be limited by the figures of the accompanying drawings.

FIG. 1 illustrates a cross-sectional side-view of a prior art compression socket.

FIG. 2 illustrates a cross-sectional side-view of an integrated circuit coupled to a circuit board through a low profile compression socket.

FIG. 3a illustrates an enlarged portion of FIG. 2.

FIG. 3b illustrates an enlarged portion of FIG. 2, where the substrate is an active substrate comprising interconnects.

FIG. 4 illustrates a cross-sectional side-view of an integrated circuit coupled to a circuit board through a low profile compression socket, the compression socket comprising compressible columns disposed in a substrate, where a test port is coupled to the substrate.

FIG. 5 illustrates a flow diagram of an embodiment for coupling an integrated circuit to a circuit board through a compression socket.

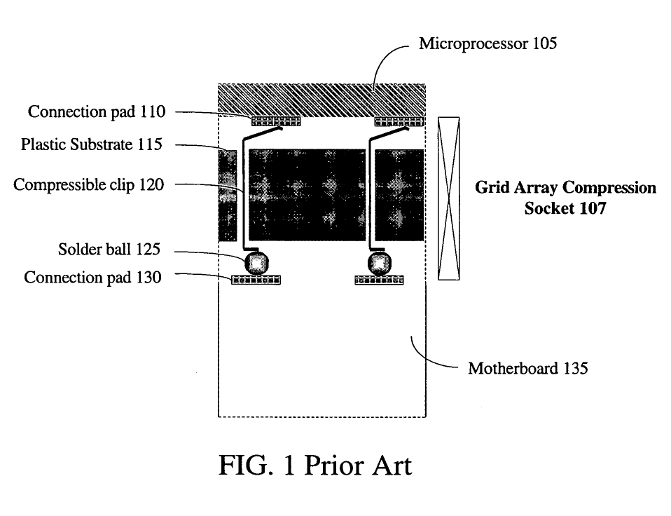

### DETAILED DESCRIPTION

In the following description, numerous specific details are set forth such as specific column heights, interposer heights, polymer bases, and other specific materials in order to provide a thorough understanding of the present invention. It will be apparent, however, to one skilled in the art that these specific details need not be employed to practice the present invention. In other instances, well known components or methods, such as well-known packaging, soldering, and force applying/compression techniques, as well as specific heat spreader/sink devices, etc., have not been described in detail in order to avoid unnecessarily obscuring the present invention.

The apparatus and method described herein are for coupling an integrated circuit to a circuit board through a low profile compression socket. It is readily apparent to one skilled in the art, that the method and apparatus disclosed herein may be implemented in any system where a device is coupled to a circuit board. For example, the apparatus and methods described herein may be used for coupling an embedded controller to a printed circuit board or a microprocessor to a motherboard.

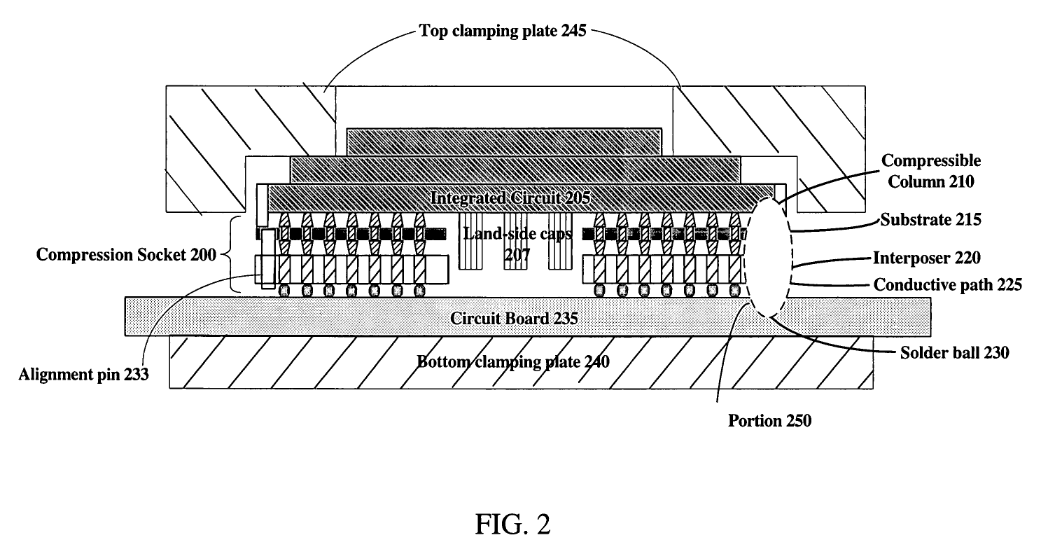

FIG. 2 illustrates a cross-sectional side-view of integrated circuit coupled to circuit board 235 through low profile compression socket 200. In one embodiment, integrated circuit 205 comprises a microprocessor in a package. As a specific example, integrated circuit 205 is packaged in a flip-chip package. Typically, in flip-chip packages active and/or passive devices, such as land-side capacitors 207, are placed on the land-side of the integrated circuit (the side of the integrated circuit where pads for contacting the lands of a socket are) to achieve better performance, power deliver, and/or signal integrity.

Additionally, integrated circuit 205 is not limited to a microprocessor in a flip-chip package. In fact, integrated circuit 205 may include a controller hub, programmable array logic (PAL) device, a clocking circuit, a microcontroller, an embedded processor, a memory device, a network controller, a graphics controller, or an audio controller. Examples of controller hubs include a north bridge or memory controller hub, a south-bridge or interconnect controller hub, or other chipset related device.

Circuit board 235 may be any printed circuit board, including graphics cards, motherboards, device interface cards (network cards, modems, universal serial bus cards, TV tuner cards, etc.), and printed circuit boards used for embedded controllers. As a specific embodiment, circuit board 235 is a multi-layered motherboard for coupling integrated circuit 205 to, as well as a plurality of other integrated circuits.

Physically and electrically coupling/contacting integrated circuit 205 to circuit board 235 is low-profile compression socket 200. Compression socket 200 comprises a plurality of compressible columns, such as compressible column 2 10, molded and/or disposed in substrate 215. In one embodiment, compressible column 210 comprises a polymer base and metal particles. One example of a polymer compound is a silicone material, such as silicone rubber, where the silicone material has very low compression-set properties. Any metal particles, including silver may be dispersed through out the polymer base to form compressible column 210. Compressible column 210, when compressed, is a conductor, which provides an electrically conductive path. An example of a polymer based compressible column is a metallized-particle interconnect (MPI) column developed by Tyco electronics.

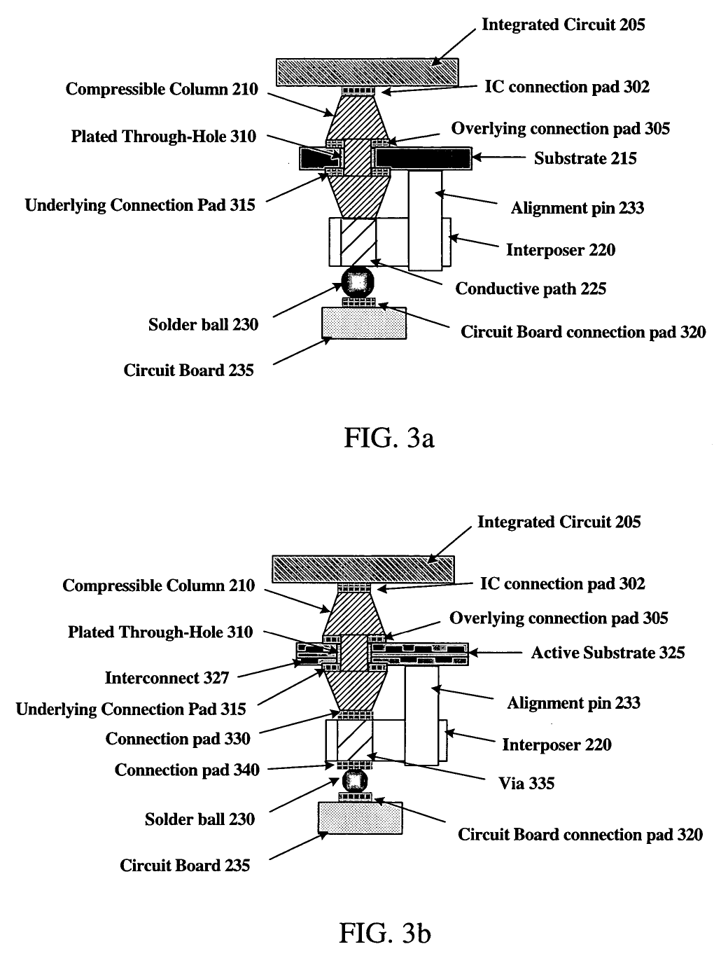

Compressible column 210 usually has a compressed height in the range of 0.030 to 0.042 inches. As a specific example, compressible column 210 has a compressed height of 0.036 inches. As stated above, compressible column 210 is disposed in substrate 215. Substrate 215 is typically used as a stiffener to hold compressible columns 210. Examples of materials used for substrate 215 include: flex cable, rigid board, rigid flex board, and fiber glass/epoxy board, such as FR4. Substrate 215 will be discussed in more detail in reference to FIGS. 3a and 3b.

Compression socket 200 further comprises interposer 220. Interposer 220 may comprise any insulating material, such as flex cable, rigid board, rigid flex board, and FR4. Interposer 220 comprises conductive paths, such as conductive path 225. Conductive path 225 is any path for making electrical connection on its overlying side (the side to electrically contact compressible columns 210 in FIG. 2) and on its underlying side (the side to electrically contact solder balls 230 and hence circuit board 235 in FIG. 2). As a first example conductive path 225 is a press-fit pin. A press-fit pin usually comprises brass plated with nickel, gold, or both. Additionally, a press-fit pin has a diameter in the range of 0.012 to 0.020 inches. Alternatively, conductive path 225 is a via with connection pads on the overlying and underlying sides of interposer 220. Interposer 220 and conductive paths 225 will be discussed in more detail in reference to FIGS. 2 and 3.

Interposer 220 has the additional advantage of adding height to low profile compression socket 200, so land-side caps 207 have enough clearance, as not to contact circuit board 207. As an example, land-side caps 207 have a height of 0.055 inches. Compressed columns disposed in a substrate, such as compressible column 210 in substrate 215, have a height of 0.036 inches. If only the compressed columns in compressions socket 200 were used, land-side caps 207 would not have enough clearance. Therefore in this example, interposer 220 with collapsed solder balls 230 have a height of 0.030 inches, creating a total height for compression socket 200 of 0.066 inches; this leaves 0.011 inches of clearance for land-side caps 207. In another embodiment, interposer 220 has a height in the range of 0.015 to 0.045 inches.

Interposer 220 may also comprise, but is not required to include, alignment apertures for alignment pins, such alignment pin 233, which is coupled to substrate/insulator 215. Alignment pins potentially aid in aligning the compressible columns with corresponding conductive paths during assembly.

Also shown in FIG. 2, is solder ball 230 to make electrical connection between conductive path 225 and connection pads, not shown, on circuit board 235. Solder ball 230 is a eutectic or lead free solder ball. However, solder ball 230 is not so limited, in that, any material to make an electrical connection between conductive path 225 and connection pads on circuit board 235 may be used.

FIG. 2 further illustrates top clamping plate 245 and bottom clamping plate 240. Typical compression sockets require some amount of compression force. One of the most common methods of compressing a compression socket includes the use of a bottom clamping plate, such as bottom clamping plate 240 mounted on the backside of a circuit board, such as circuit board 235. Top clamping plate 245, using a lever or other mechanical device, clamps to bottom clamping plate 240, which results in force on integrated circuit 205 and the compression of compressible columns 210 in compression socket 200. When compressed electrical contact between a first set of connection pads coupled to integrated circuit 205 and a second set of corresponding connection pads coupled to circuit board 235 is made through compressed column 210, conductive path 225, and solder ball 230.

An alternative to top clamping plate 245 and bottom clamping plate 240 is the use of tension pins to couple integrated circuit board 235. Co-pending application with application Ser. No. ______ entitled “Hybrid Compression Socket Connector for Integrated Circuits,” discloses an apparatus and method for coupling an integrated circuit to a circuit board using tension pins to engage corresponding barrels in the circuit board.

Turning to FIG. 3a, an enlarged portion 250 of FIG. 2 is illustrated. Integrated circuit connection pad 302 is coupled to integrated circuit 205. Compressible column 210, when compressed, makes electrical connection with connection pad 302. Also illustrated in FIG. 3a is substrate 215 comprising plated through hole/aperture 310 with overlying connection pad 305 on the overlying side of substrate 215 and underlying connection pad on the underlying side of substrate 215. Therefore, when compressible column 210 is compressed it further makes electrical connection with overlying connection pad 305 and underlying connection pad 315. Resistors may also be placed near each connection pad using commonly know resistive layer technology.

Moreover, compressible columns 210, when compressed, make electrical connection with conductive path 225. Conductive path 225, as stated above, may include a press-fit pin or connection pads with a via. Consequently, when compression socket 200 is compressed, conductive path 225 makes electrical connection with compressible column 210 and circuit board connection pad 320 through solder ball 230.

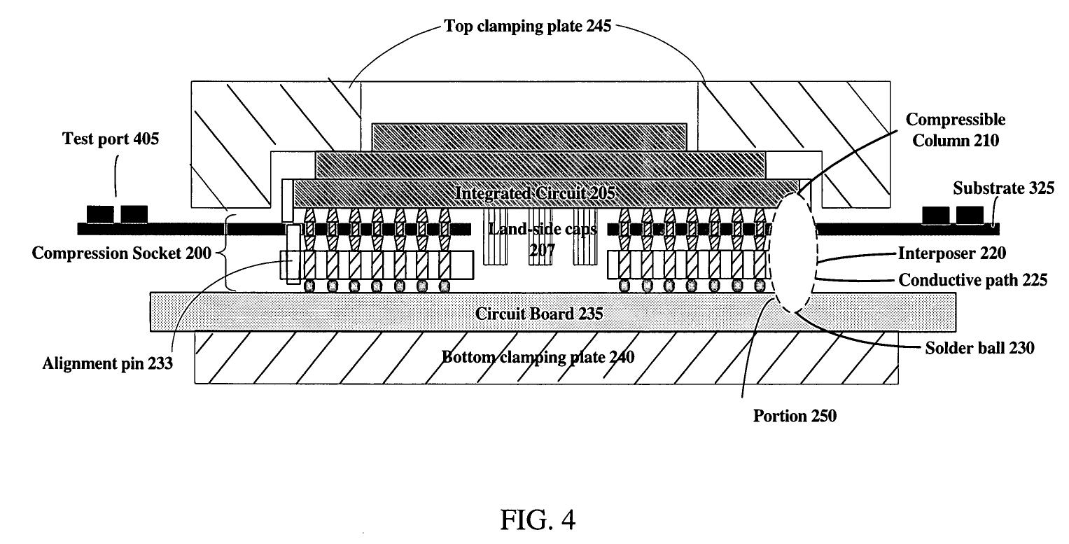

FIG. 3b illustrates another embodiment of compression socket 200. In FIG. 3b substrate 215 is active substrate 325 comprising interconnects. As aforementioned, when compressed, compressible columns 210 make electrical connection with overlying and underlying connection pads 310 and 315. In addition, overlying connection pad 310, underlying connection pad, and/or plated through hole 310 may electrically contact one interconnect, a plurality of interconnects, or a ground plane in active substrate 325. Furthermore, interconnects, such as interconnect 327, may make electrical connection to other devices, other interconnects, test ports (discussed in more detail in reference to FIG. 4), a ground plane, or a power plane.

FIG. 3b also illustrates connection pad 330, via 335, and an underlying connection pad 340 in place of a press-fit pin for conductive path 225. Just as substrate 215 may be used as an active substrate, interposer 220 may be used as an active interposer, where overlying and underlying connections pads 330 and 340 make electrical connection with interconnects present in interposer 220.

Referring to FIG. 4, an embodiment of compression socket 200 is shown. Substrate 325 is shown, where substrate 325 extends laterally beyond integrated circuit 205. Also illustrated, is test port 405 coupled to substrate 215. Test port/socket 405 includes any port for connecting to an external device. Examples of external devices for connection to test port 405 include: (1) logic analyzer; (2) an oscilloscope; and (3) a spectrum analyzer. Test port 405 may also make electrical connection to interconnects, such as interconnect 307 shown in FIG. 3b. Therefore, a test port may be provided in compression socket 200 that has electrical connection to pads of the microprocessor through active substrate 325, plated through hole 310/connection pads 305 and 315, and compressible column 310.

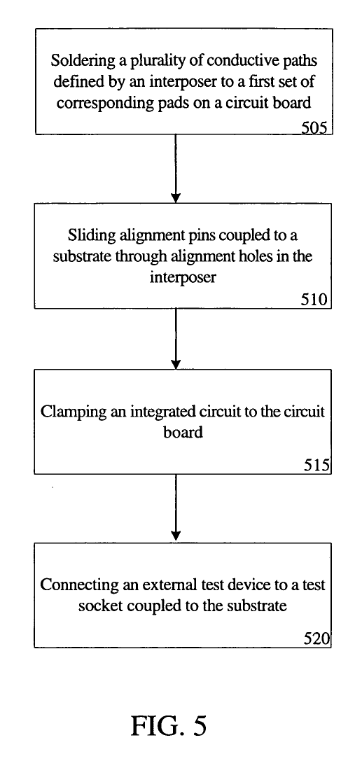

FIG. 5 illustrates flow diagram 300 of an embodiment for coupling an integrated circuit, such as integrated circuit 205, to a circuit board, such as circuit board 235, through a compression socket, such as compression socket 200. First, in block 505, a plurality of conductive paths, which are disposed in/defined by an interposer, are soldered to a first set of corresponding pads coupled to a circuit board. In block 510, alignment pins, which are coupled to a substrate, are slid through alignment apertures in the interposer to align a plurality of compressible columns, which pass through the substrate, with the plurality of conductive paths.

Next, in block 515 an integrated circuit is clamped to the circuit board to compress the compressible columns. In one embodiment, clamping includes clamping a top clamping plate to a bottom clamping plate to compress the compressible columns. As an alternative, tension pins are inserted into corresponding barrels in the circuit board, as described in co-pending application with application Ser. No. ______ entitled “Hybrid Compression Socket Connector for Integrated Circuits,” to clamp the integrated circuit to the circuit board and to compress the compressible columns. Finally, in block 520 an external test device, such as an oscilloscope, logic analyzer, spectrum analyzer, or other external device.

As can be seen from the discussion above, adequate clearance for active or passive devices place on the land-side of an integrated circuit is provided in a low profile compression socket comprising a substrate with compressible columns and an interposer with conductive paths, without forfeiting beneficial high-frequency inductance and capacitance characteristics. Furthermore, the substrate may further comprise interconnects and a test port for connecting to an external test device; this potentially allows for quick and easy connection of external devices in testing situation.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. An apparatus comprising:
a plurality of compressible polymer-based columns disposed in a substrate, the plurality of compressible columns, when compressed, to make an electrical connection to a first set of connection pads coupled to an integrated circuit; and
a plurality of conductive paths disposed in an interposer to electrically contact (1) the plurality of compressible polymer-based columns and (2) a second set of connection pads coupled to a circuit board.

2. The apparatus of claim 1, wherein the compressible polymer-based columns comprise a polymer base and silver particles.

3. The apparatus of claim 2, wherein the polymer base comprises silicone rubber.

4. The apparatus of claim 2, wherein the plurality of conductive paths include press-fit pins, each press-fit pin comprising brass plated with nickel and gold.

5. The apparatus of claim 4, wherein the interposer comprises FR4 material, and wherein each press-fit pin has a diameter in the range of 0.012 to 0.020 inches.

6. The apparatus of claim 2, wherein each of the plurality of conductive paths comprise a via, an underlying connection pad on the underlying side of the interposer, and an overlying connection pad on the overlying side of the interposer.

7. The apparatus of claim 1, wherein the substrate comprises a material selected from a group consisting of flex cable, rigid board, rigid flex board, and FR4.

8. The apparatus of claim 7, wherein the substrate further comprises plated through holes having connection pads on the underlying and overlying sides of the substrate, wherein the connection pads are to make electrical connection with interconnects present in the substrate.

9. The apparatus of claim 8, wherein at least one of the interconnects makes electrical connection to a ground plane.

10. The apparatus of claim 8, wherein at least one resistor is placed near each connection pad using resistive layer technology.

11. The apparatus of claim 8, wherein the substrate further comprises a test port to connect to an external test device.

12. The apparatus of claim 1, wherein the compressible polymer columns have a height in the range of 0.030 to 0.042 inches, the interposer has a height in the range of 0.015 to 0.045 inches.

13. An apparatus comprising:
a substrate comprising a compressible column disposed in a plated through hole, the compressible column, when compressed, to make electrical connection with (1) an interconnect formed in the substrate and (2) with a first connection pad coupled to a microprocessor;
a test port coupled to the substrate to make electrical connection with (1) the interconnect and (2) an external test device; and
an interposer having a conductive path to make electrical connection with (1) the compressible column and (2) a second connection pad coupled to a circuit board.

14. The apparatus of claim 13, wherein the compressible column comprises a polymer base and silver particles.

15. The apparatus of claim 14, wherein the interposer comprises FR4 material, and wherein the conductive path in the interposer is a press-fit pin with a diameter in the range of 0.012 to 0.020 inches.

16. The apparatus of claim 15, wherein the substrate comprises a material selected from a group consisting of flex cable, rigid board, and rigid flex board.

17. The apparatus of claim 13, wherein the substrate further comprises a ground plane.

18. The apparatus of claim 16, wherein the compressible column has a height in the range of 0.030 to 0.042 inches and the interposer has a height in the range of 0.015 to 0.045 inches.

19. The apparatus of claim 13, wherein the external test device is selected from a group consisting of a logic analyzer, an oscilloscope, and a spectrum analyzer.

20. A system comprising.
an integrated circuit comprising a first set of connection pads;
a plurality of compressible columns molded in an insulator, the plurality of compressible columns electrically connected to the first set of connection pads;
a plurality of alignment pins coupled to the insulator;
an interposer comprising (1) a plurality of conductive paths electrically connected to the compressible columns and (2) a plurality of alignment apertures for the plurality of alignment pins to pass through; and
a circuit board comprising a second set of connection pads soldered to the plurality of conductive paths.

21. The apparatus of claim 20, wherein the integrated circuit comprises a microprocessor and the circuit board is a motherboard.

22. The apparatus of claim 20, wherein the compressible columns comprise a polymer base and silver particles.

23. The apparatus of claim 22, wherein the insulator comprises a material selected from a group consisting of flex cable, rigid board, rigid flex board, and FR4.

24. The apparatus of claim 22, wherein the conductive paths comprise press-fit pins.

25. The apparatus of claim 22, wherein the conductive paths comprise an overlying connection pad on the overlying side of the interposer, an underlying pad on the underlying side of the interposer, and a via making electrical connection between the overlying and underlying connection pads.

26. A method comprising:
soldering a plurality of conductive paths defined by an interposer to a first set of corresponding pads on a circuit board; and
sliding alignment pins coupled to a substrate through alignment apertures in the interposer to align a plurality of compressible polymer-based columns, which pass through the substrate, with the plurality of conductive paths.

27. The apparatus of claim 26, further comprising connecting an external test device to a test socket coupled to the substrate.

28. The apparatus of claim 26, further comprising clamping an integrated circuit to the circuit board to compress the compressible polymer-based columns.

29. The apparatus of claim 28, wherein clamping the integrated circuit to the circuit board comprises clamping a top clamping plate to a bottom clamping plate.

30. The apparatus of claim 28, wherein clamping the integrated circuit to the circuit board comprises inserting tension pins into corresponding barrels in the circuit board.

31. The apparatus of claim 28, wherein the conductive paths comprise press-fit pins.

32. The apparatus of claim 31, wherein the circuit board is a motherboard and the integrated circuit is a microprocessor.

33. The apparatus of claim 32, wherein each compressible polymer-based columns comprise a polymer base and silver particles.
